(19) United States
(12) Patent Application Publication
(10) Pub. No.: US 2025/0069827 A1
(43) Pub. Date: Feb. 27, 2025

(54) High-Reliability Multi-Function Switch

(71) Applicant: Shiju Wang, Irvine, CA (US)

(72) Inventor: Shiju Wang, Irvine, CA (US)

(21) Appl. No.: 18/589,178

(22) Filed: Feb. 27, 2024

Related U.S. Application Data
(60) Provisional application No. 63/533,791, filed on Aug. 21, 2023.

(51) Int. Cl. H01H 13/20; H01H 13/04; H01H 13/14; H05K 1/18

(52) U.S. Cl. CPC H01H 13/20; H01H 13/04; H01H 13/14; H05K 1/181; H05K 2201/10053

(57) ABSTRACT

A high-reliability multi-function switch is a device that enables the determination of the “ON” and “OFF” functionality of a host application as well as the operating speed of the host application. To do so, the device includes at least one push button switch and at least one pressure transducer. The at least one push button switch enables the determination of the power functionality of the host application. The at least one push button switch triggers the host application to perform different functionalities according to the current position of the at least one push button switch. The at least one pressure transducer enables the determination of the operating speed of the host application by measuring the pressure applied to engage the at least one push button switch. The at least one pressure transducer further increase the reliability of the device by eliminating friction caused by mechanical contact between moving components.

### FIELD OF THE INVENTION

The present invention relates generally to electrical and electronic components for circuit control and data input. More specifically, the present invention provides a novel electronic device that incorporates a mechanical switch with a pressure transducer.

### BACKGROUND OF THE INVENTION

Trigger switches have been developed to enable users to momentarily change the status of a circuit, such as momentarily activating or deactivating the circuit. For example, trigger switches have been implemented in hand-held power tools such as drills, jigsaws, etc. A trigger switch typically includes three functions: power control, speed control, and direction control. The trigger switch provides two outputs which determine the power control function. The first output is active when the switch is mechanically set to the “OFF” position, and the second output is active when the switch is mechanically set to the “ON” position. Further, the trigger switch provides a resistive output which determines the speed of the power tool's operation. The output's resistance (relative to system ground) is proportional to the movement of the trigger. At one extreme mechanical position of the trigger switch, the output's resistance is a minimum resistance. At the other extreme mechanical position of the trigger switch, the output's resistance is a maximum resistance. As the trigger switch is mechanically moved across the designated range of motion, the resistance changes proportionally with said movement.

Further, the trigger switch provides a mechanical control which activates one of two switches that determine whether the application shall operate in a forward mode or a reverse mode. When the mechanical control is in one extreme position, the first output is active, and the second output is inactive. When the mechanical control is in the other extreme position, the first output is inactive, and the second output is active. The trigger switch presently used in such applications provide average lifetimes of around 100,000 cycles or activations. Manufacturers continuously seek to improve the lifetimes of the trigger switch such that 1,000,000 cycles or activations may be achieved. However, the reliability of a trigger switch is typically limited by the speed control element. The speed control element is typically implemented using a potentiometer structure in which the conductive wiper makes physical contact with a resistive material. As the wiper is moved across the surface of the resistive material, the resistance of the associated output changes. Because the wiper makes physical contact with the resistive material, the resistive material and/or wiper eventually wear away over many cycles of use. After prolonged use, the resistive material may completely wear away, rendering the speed control non-functional.

Therefore, an objective of the present invention is to improve the reliability of trigger switches by eliminating the mechanical contact in the speed control function of the trigger switch. This enables the trigger switch to have greater reliability over the switch's lifetime. Another objective of the present invention is to provide a novel switch structure for the power control function of the switch. This enables the trigger switch to have a very compact structure and be more cost effective. Further, the novel structure of the trigger switch allows the switch to have low noise and be more robust. The structure of the trigger switch can also be waterproofed for increased reliability and greater functionality. Additional features and benefits of the present invention are further disclosed in the sections below.

### SUMMARY OF THE INVENTION

An objective of the present invention is to provide a high-reliability multi-function switch. The present invention utilizes a combination of a low-cost, low-profile pressure transducer and a unique push button switch to replace the potentiometer used in conventional trigger switch applications. This combination replaces the speed control and power control functions of a conventional trigger switch. The present invention can implement the pressure transducer and the push button switch on a Printed Circuit Board (PCB) for a compact and low-cost implementation that can accommodate additional functionalities. For example, the present invention may further include a forward switch and a reverse switch.

In the preferred embodiment, when the push button switch is in a resting position, a switch plunger of the push button switch contacts the metal conductor of a contact corresponding to the “OFF” contact. When the push button switch is pressed a given distance, the switch plunger ceases to contact the “OFF” Contact. If the switch plunger is pressed a further distance, the switch plunger contacts the metal conductor of a contact corresponding to the “ON” Contact. The mechanical movement of the switch plunger and change of contact enables the power control function of the present invention. Further, because the structure of the present invention does not employ a motion which causes the switch plunger to rub across the contacts, the physical wear on the associated contact surfaces is minimized. In addition, the present invention is designed such that the switch plunger can also activate the pressure transducer. The structure of the present invention is designed to enable the switch plunge to contact the pressure transducer when the switch plunger is pressed and has moved to the position at which the “ON” contact becomes active. The switch plunger is designed such that the range of motion allows the switch plunger to exert enough pressure on the pressure transducer to provide the necessary variation in resistivity of the pressure transducer to support the desired application.

### BRIEF DESCRIPTION OF THE DRAWINGS

FIG. 1 is a top front perspective view of the present invention.

FIG. 2 is a bottom rear perspective view thereof.

FIG. 3 is a front view thereof.

FIG. 4 is a vertical cross-sectional view taken along line 4-4 in FIG. 3.

FIG. 5 is a top front perspective view of the present invention, wherein a switch plunger is shown pressed into a switch housing.

FIG. 6 is a front view thereof.

FIG. 7 is a vertical cross-sectional view taken along line 7-7 in FIG. 6.

FIG. 8 is a top front perspective view of the present invention, wherein the present invention is shown within a hermetic seal.

FIG. 9 is a front view thereof.

FIG. 10 is a vertical cross-sectional view taken along line 10-10 in FIG. 9.

FIG. 11 is a top front perspective view of a first embodiment of the present invention, wherein the present invention is shown with a Printed Circuit Board (PCB).

FIG. 12 is a side view thereof.

FIG. 13 is a top front perspective view of a second embodiment of the present invention, wherein the present invention is shown with the Printed Circuit Board (PCB).

FIG. 14 is a bottom rear perspective view thereof.

FIG. 15 is a top front exploded perspective view thereof.

FIG. 16 is a bottom rear exploded perspective view thereof.

FIG. 17 is a front view thereof.

FIG. 18 is a vertical cross-sectional view taken along line 18-18 in FIG. 17.

FIG. 19 is a top front perspective view of the second embodiment of the present invention, wherein the switch plunger is shown pressed into the switch housing, and wherein the present invention is shown with the PCB.

FIG. 20 is a front view thereof.

FIG. 21 is a vertical cross-sectional view taken along line 21-21 in FIG. 20.

FIG. 22 is a diagram of the electronic connections of the present invention.

### DETAIL DESCRIPTIONS OF THE INVENTION

All illustrations of the drawings are for the purpose of describing selected versions of the present invention and are not intended to limit the scope of the present invention.

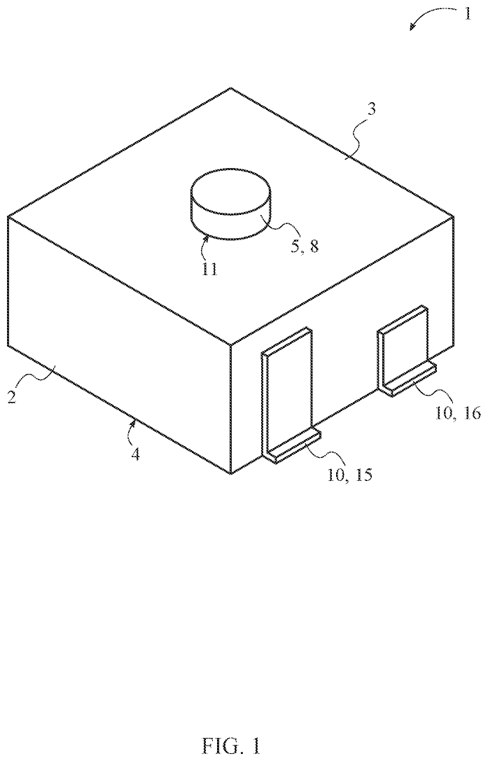

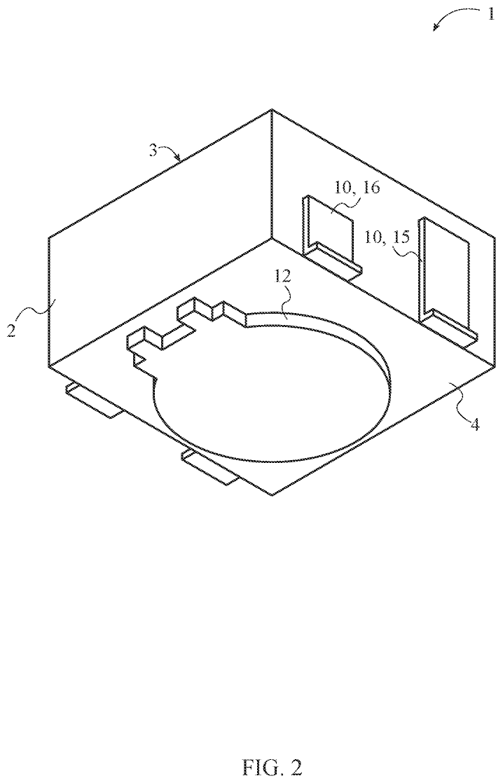

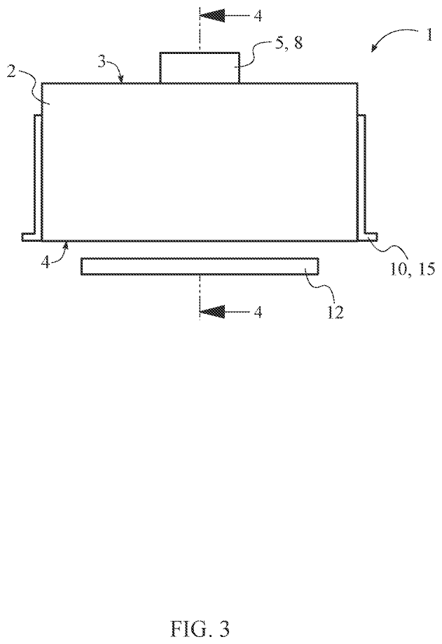

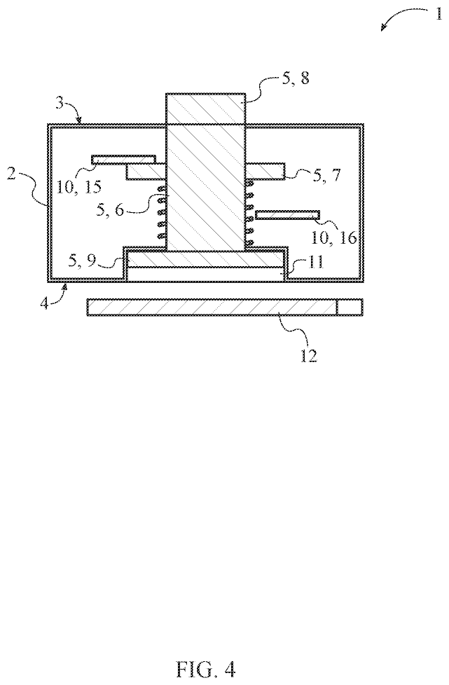

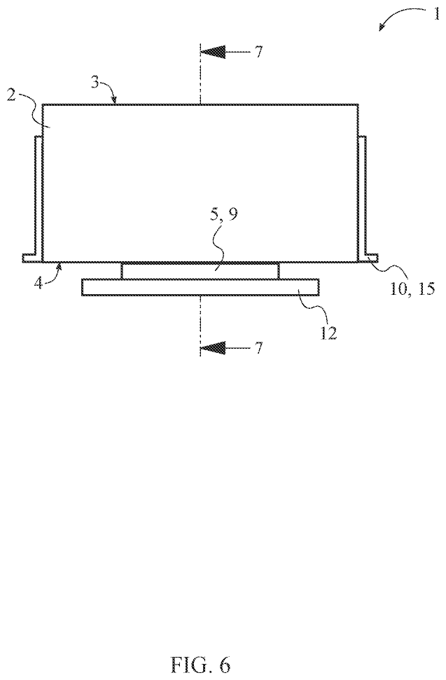

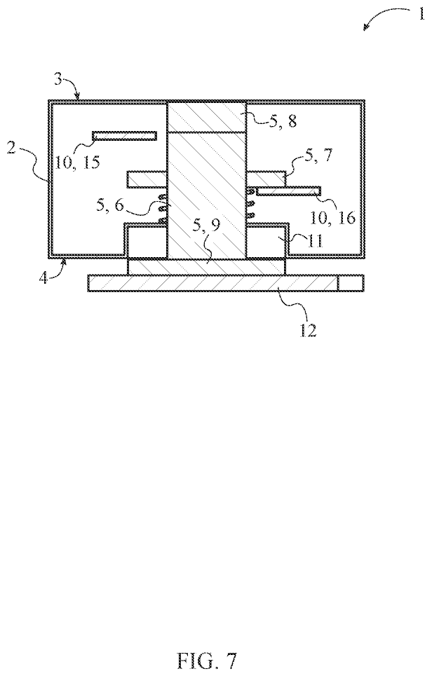

The present invention discloses a high-reliability multi-function switch. The present invention is designed to enable the determination of the “ON” and “OFF” functionality of the host application as well as the operating speed of the host application. As can be seen in FIG. 1 through 7, the present invention comprises at least one push button switch 1 and at least one pressure transducer 12. The at least one push button switch 1 enables the determination of the power functionality of the host application. In other words, the at least one push button switch 1 triggers the host application to perform different functionalities according to the current position of the at least one push button switch 1. On the other hand, the at least one pressure transducer 12 enables the determination of the operating speed of the host application by measuring the pressure applied to engage the at least one push button switch 1.

The general configuration of the aforementioned components enables the implementation of a high-reliability trigger switch and similar input devices. As can be seen in FIG. 1 through 7, the at least one push button switch 1 is preferably designed as a low-profile device that comprises a switch housing 2, a switch plunger 5, at least one switch contact 10, and a plunger channel 11. The switch housing 2 is designed to protect the different components of the at least one push button switch 1 without obstructing the operation of the moving components. The plunger channel 11 is designed to enable the movement of the switch plunger 5 through the switch housing 2. The switch plunger 5 is designed to enable the selective activation of the at least one switch contact 10. The switch plunger 5 is also designed to selectively activate the at least one pressure transducer 12. Further, the at least one switch contact 10 is designed to trigger a corresponding function on the host application.

As can be seen in FIG. 1 through 7, in the preferred embodiment, the plunger channel 11 traverses through the switch housing 2 to enable the switch plunger 5 to move through the switch housing 2 and contact the at least one switch contact 10. The plunger channel 11 also enables the switch plunger 5 to contact the at least one pressure transducer 12. The at least one switch contact 10 is mounted within the switch housing 2 to secure the at least one switch contact 10 inside the switch housing 2. The at least one switch contact 10 is also positioned adjacent to the switch plunger 5 so that the metal contacts of the switch plunger 5 can complete a conductive path with the at least one switch contact 10 to activate a specific functionality of the host application. Further, the switch plunger 5 is slidably mounted within the plunger channel 11 so that the switch plunger 5 is secured to the switch housing 2 while enabling a predetermined range of motion for the switch plunger 5. Furthermore, the at least one pressure transducer 12 is mechanically co-located with the switch plunger 5 along the plunger channel 11 to enable the switch plunger 5 to selectively activate the at least one pressure transducer 12. In other words, the at least one pressure transducer 12 is arranged in such a way that the switch plunger 5 can contact the at least one pressure transducer 12.

As previously discussed, the at least one push button switch 1 is designed to enable the selective momentary activation of the at least one switch contact 10 as well as the at least one pressure transducer 12. As can be seen in FIG. 1 through 7, the switch plunger 5 may comprise a spring-loaded body 6, at least one body contact 7, a first plunger end 8, and a second plunger end 9. The spring-loaded body 6 enables the automatic reset of the positioning of the switch plunger 5 if no force is being applied to the switch plunger 5. The first plunger end 8 and the second plunger end 9 correspond to the terminal ends of the switch plunger 5. The at least one body contact 7 enables the selective activation of the at least one switch contact 10. In addition, the switch housing 2 may comprise a first housing face 3 and a second housing face 4. The first housing face 3 preferably corresponds to the housing face where the user engages the switch plunger 5. On the other hand, the second housing face 4 corresponds to the housing face where the switch plunger 5 engages the at least one pressure transducer 12. In the preferred embodiment, the first plunger end 8 is positioned opposite to the second plunger end 9 along the spring-loaded body 6 due to the elongated structure of the switch plunger 5. Similarly, the first housing face 3 is positioned opposite to the second housing face 4 across the switch housing 2. In addition, the plunger channel 11 traverses from the first housing face 3 to the second housing face 4 so that the switch plunger 5 can move through the switch housing 2 from the first housing face 3 to the second housing face 4 without obstruction. Further, as can be seen in FIG. 1 through 7, the spring-loaded body 6 is slidably mounted within the plunger channel 11 to secure the spring-loaded body 6 to the switch housing 2. Further, the at least one body contact 7 is laterally mounted onto the spring-loaded body 6 so that the at least one body contact 7 can engage with the at least one switch contact 10. The first plunger end 8 is positioned adjacent to the first housing face 3 while the second plunger end 9 is positioned adjacent to the second housing face 4. Further, the at least one pressure transducer 12 is positioned adjacent to the second housing face 4 to position the at least one pressure transducer 12 in range of the second plunger end 9. In addition, the at least one pressure transducer 12 is axially aligned with the second plunger end 9 to ensure that the second plunger can contact the at least one pressure transducer 12.

The arrangement of the at least one push button switch 1 and the at least one pressure transducer 12 enable the select activation of the at least one switch contact 10 and the at least one pressure transducer 12. For example, as can be seen in FIG. 1 through 4, in a resting configuration, the first plunger end 8 is positioned external to the plunger channel 11, the at least one body contact 7 is positioned offset the at least one switch contact 10, and the second plunger end 9 is positioned within the plunger channel 11. In other words, the at least one body contact 7 does not contact the at least one switch contact 10, and the second plunger end 9 does not contact the at least one pressure transducer 12.

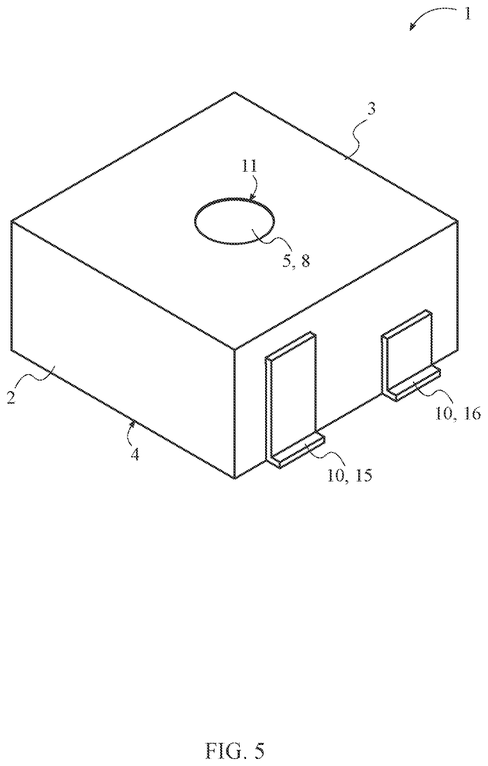

As can be seen in FIG. 5 through 7, in a pressed configuration, the first plunger end 8 is positioned within the plunger channel 11, the at least one body contact 7 is in physical contact with the at least one switch contact 10, the second plunger end 9 is positioned external to the plunger channel 11, and the second plunger end 9 is in physical contact with the at least one pressure transducer 12. In other words, the first plunger end 8 is pressed into the plunger channel 11 by the user, which causes the at least one body contact 7 to engage the at least one switch contact 10. In addition, the second plunger end 9 is pushed out of the plunger channel 11, which allows the second plunger end 9 to contact the at least one pressure transducer 12. Further, the force applied to the first plunger end 8 is transmitted via the spring-loaded body 6 to the second plunger end 9 and onto the at least one pressure transducer 12 so that the at least one pressure transducer 12 can read the resistive corresponding to the force applied to the at least one pressure transducer 12. In one embodiment, the output of the at least one pressure transducer 12 may be linear in proportion to the pressure exerted onto the at least one pressure transducer 12. In another embodiment, the output of the at least one pressure transducer 12 may be non-linear in proportion to the pressure exerted onto the at least one pressure transducer 12.

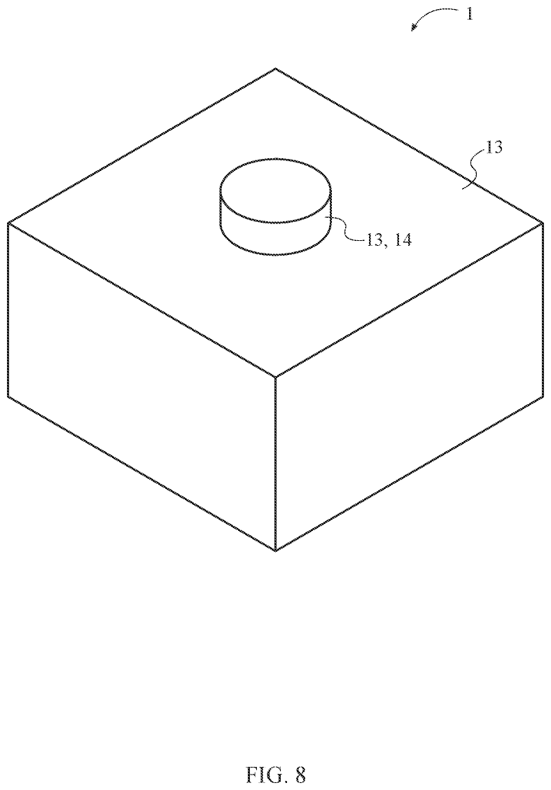

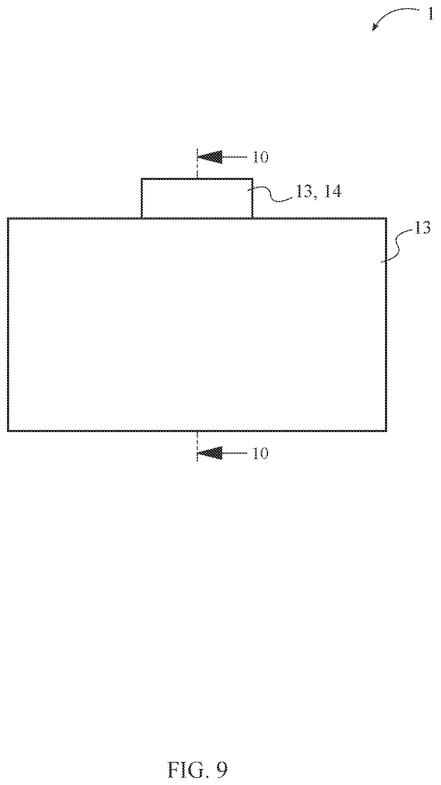

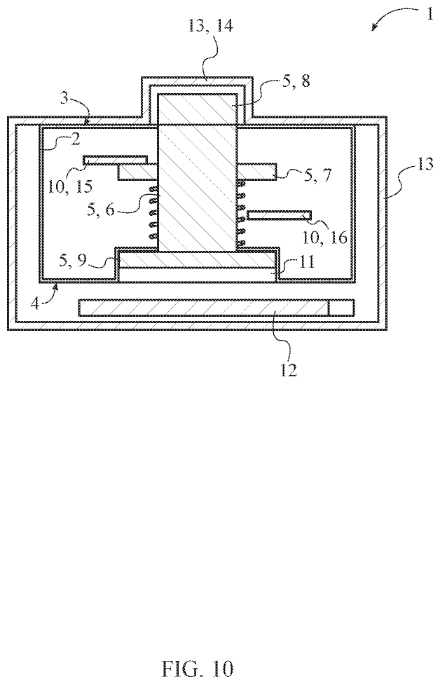

Further, in some embodiments, the at least one push button switch 1 and the at least one pressure transducer 12 may be sealed such that contaminants including, but not limited to, fluids are prevented from affecting the operation the electrical and/or electronic components. As can be seen in FIG. 8 through 10, the present invention may further comprise a hermetic seal 13 which protects the present invention from external contaminants and other foreign substances. The hermetic seal 13 comprises a button interface 14 which allows the user to engage the switch plunger 5 through the hermetic seal 13. So, the button interface 14 is externally and hermetically integrated into the hermetic seal 13 to allow the user to engage the first plunger end 8. The at least one push button switch 1 and the at least one pressure transducer 12 are mounted within the hermetic seal 13 so that the hermetic seal 13 can prevent external contaminants and other foreign substances from being in contact with either component. Further, the first plunger end 8 is positioned adjacent to the button interface 14 so that when the user presses the button interface 14, the user is also pressing on the first plunger end 8. In other embodiments, different protective mechanisms can be implemented to protect the electrical and electronic components of the present invention.

As previously discussed, the present invention enables the determination of different functionalities of the host application using the at least one push button switch 1. To do so, several switch contacts can be implemented to allow the user to selectively engage the desired functionality. As can be seen in FIG. 1 through 7, the at least one switch contact 10 may be a first switch contact 15 and a second switch contact 16. In one embodiment, the first switch contact 15 preferably corresponds to the “OFF” contact and the second switch contact 16 corresponds to the “ON” contact. In other embodiments, the first switch contact 15 and the second switch contact 16 can be assigned to different functions for the host application. Further, the first switch contact 15 is positioned adjacent to the first housing face 3, while the second switch contact 16 is positioned adjacent to the second housing face 4. This way, the movement of the switch plunger 5 activates the different switch contacts as the at least one body contact 7 is moved to different positions along the plunger channel 11.

As can be seen in FIG. 1 through 7, in the resting configuration, the at least one body contact 7 is positioned offset to the second switch contact 16, and the at least one body contact 7 is in electrical contact with the first switch contact 15. In other words, when the switch plunger 5 is not pressed by the user, the at least one body contact 7 is normally in electrical contact with the first switch contact 15. This way, the at least one push button switch 1 is normally “OFF” when not engaged. On the other hand, in the pressed configuration, the at least one body contact 7 is positioned offset to the first switch contact 15, and the at least one body contact 7 is in electrical contact with the second switch contact 16. In other words, the second switch contact 16 can only be activated by the user pressing the switch plunger 5 into the switch housing 2 to move the at least one body contact 7 towards the second switch contact 16. The location of the body contact 7 and the second switch contact 16 may be determined such that when the body contact 7 makes electrical contact with the second switch contact 16, the second plunger end 9 makes initial contact with the surface of the at least one pressure transducer 12. Due to the design of the spring-loaded body 6, the switch plunger 5 moves back to the resting configuration if the user does not keep pressing on the switch plunger 5. In other embodiments, additional switch contacts and/or body contacts can be provided to enable the selective activation of different functions on the host application.

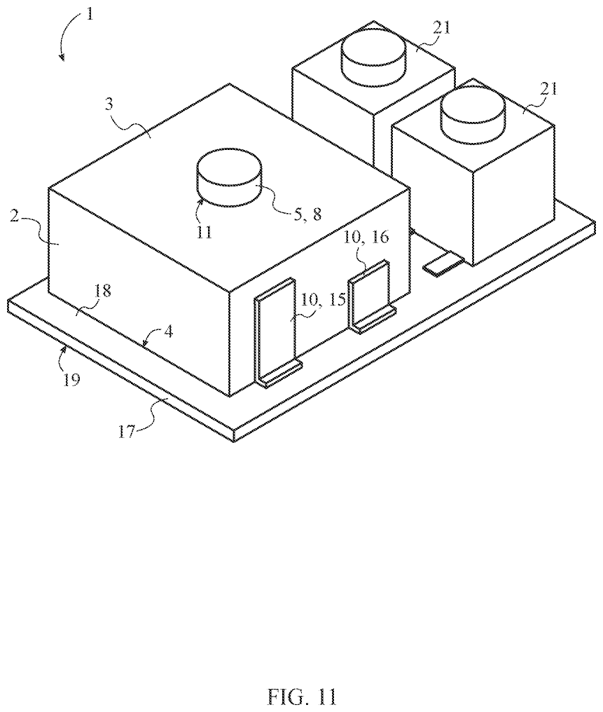

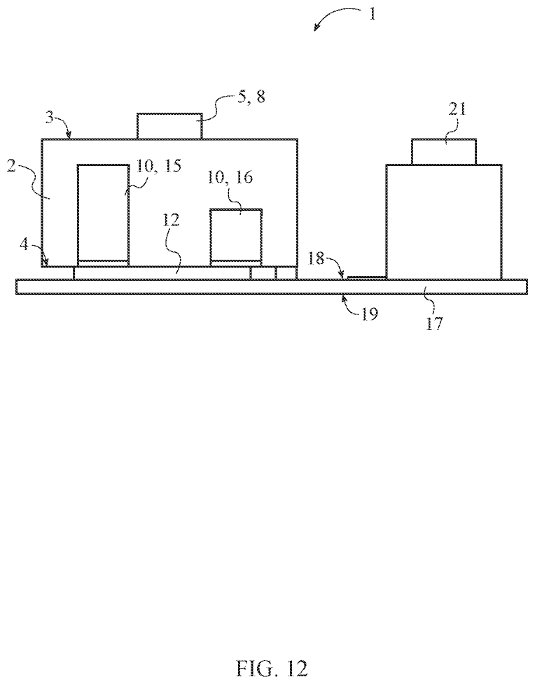

As previously discussed, the present invention can be implemented with other electronic components to enhance the functionality with the host application. In some embodiments, the present invention may further comprise at least one printed circuit board (PCB) 17 that accommodates the different components of the present invention. The switch housing 2 and the at least one pressure transducer 12 are mounted onto the at least one PCB 17 to secure the at least one push button switch 1 and the at least one pressure transducer 12 to the at least one PCB 17. In addition, when the at least one push button switch 1 and the at least one pressure transducer 12 are mounted onto the at least one PCB 17, the at least one push button switch 1 and the at least one pressure transducer 12 are still arranged so that the components are co-located with each other on the at least one PCB 17. As can be seen in FIGS. 11 and 12, in a first embodiment, the switch housing 2 and the at least one pressure transducer 12 are mounted onto the at least one PCB 17 in such a way that the at least one pressure transducer 12 is mounted onto a surface of the at least one PCB 17. In addition, the switch housing 2 is mounted onto the at least one pressure transducer 12, opposite the at least one PCB 17. As a result, the at least one pressure transducer 12 is positioned in between the at least one PCB 17 and the switch housing 2. This way, the at least one PCB 17 serves as a supporting structure for the at least one pressure transducer 12 when the switch plunger 5 is pressed against the at least one pressure transducer 12.

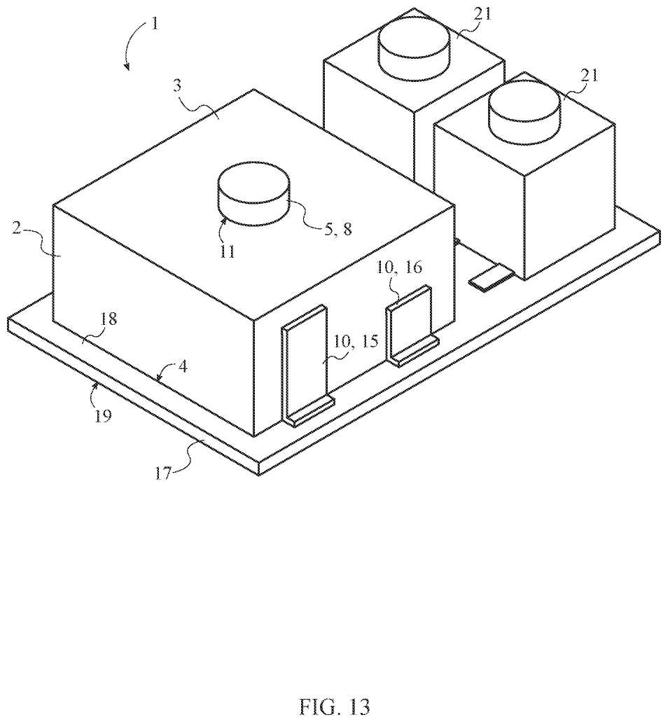

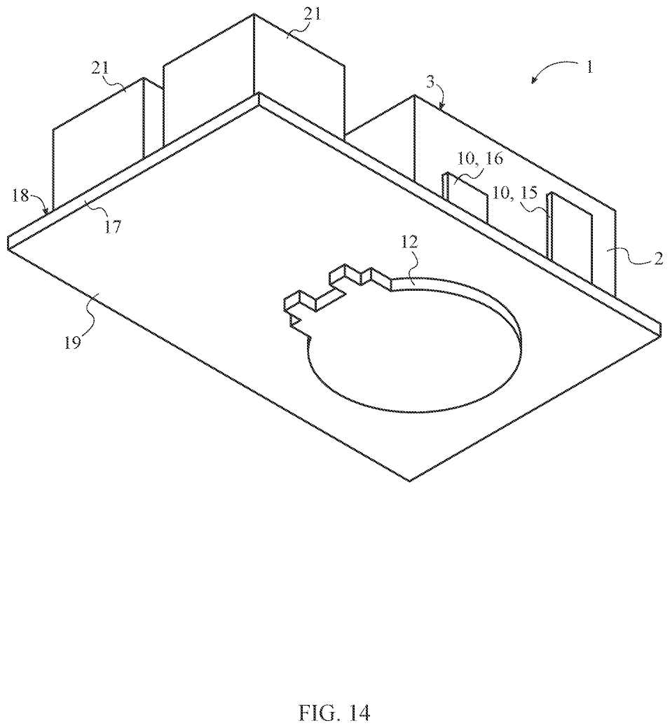

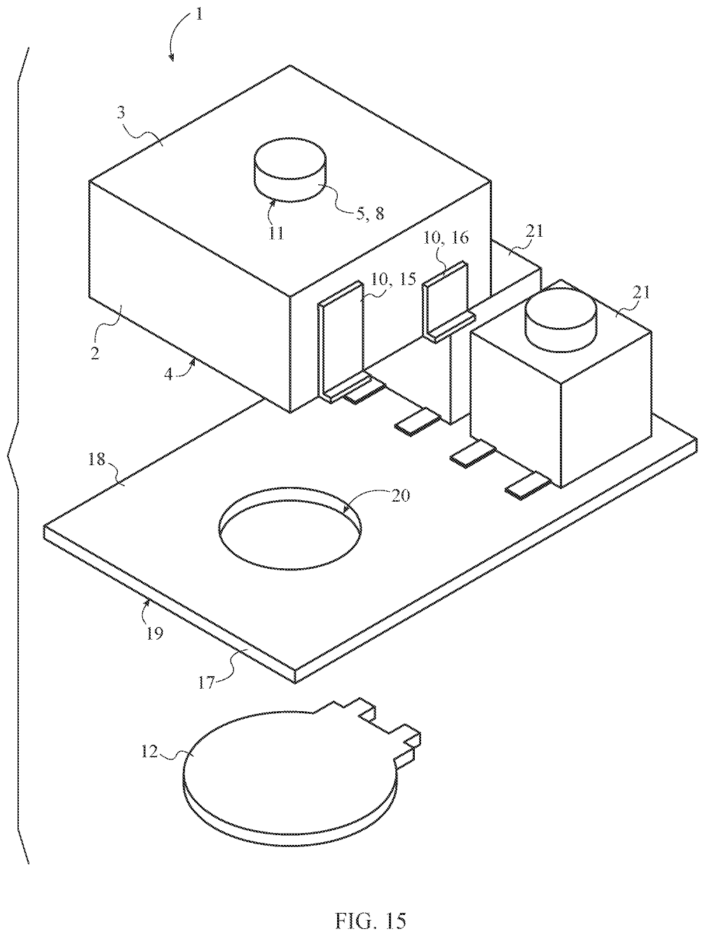

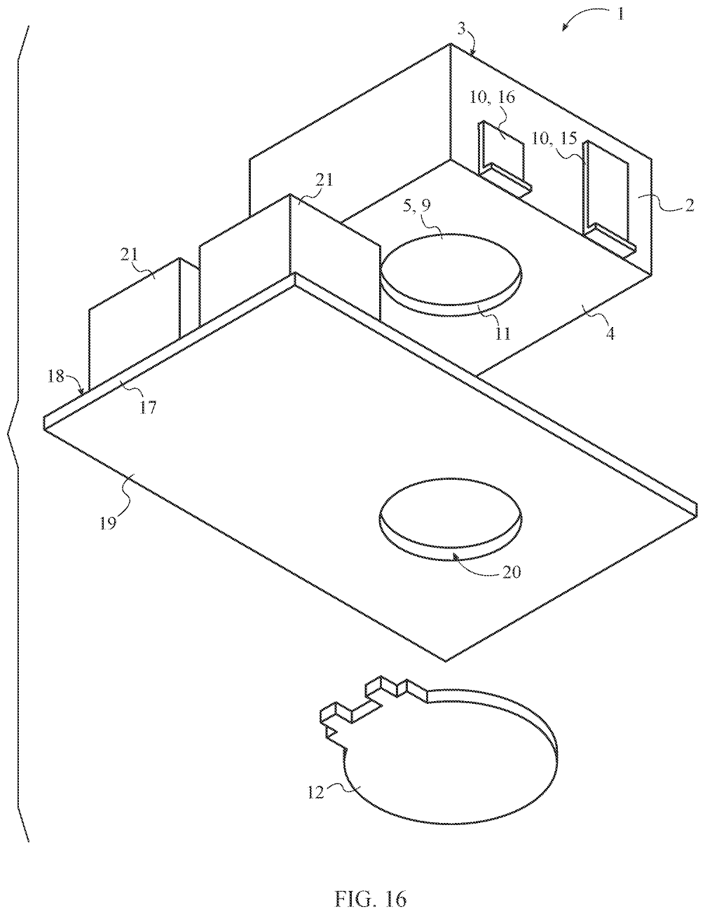

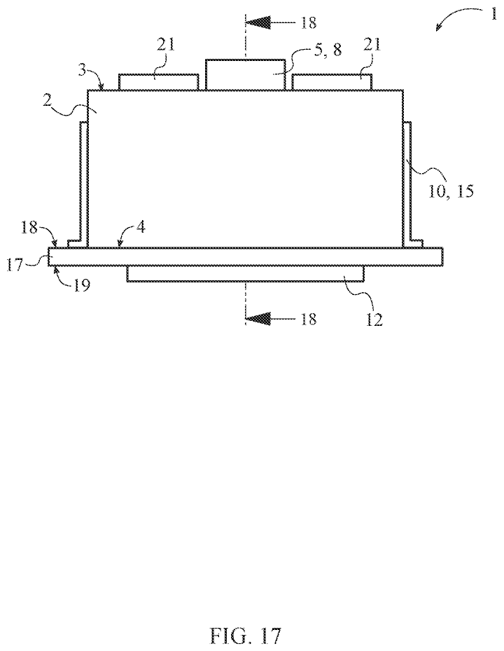

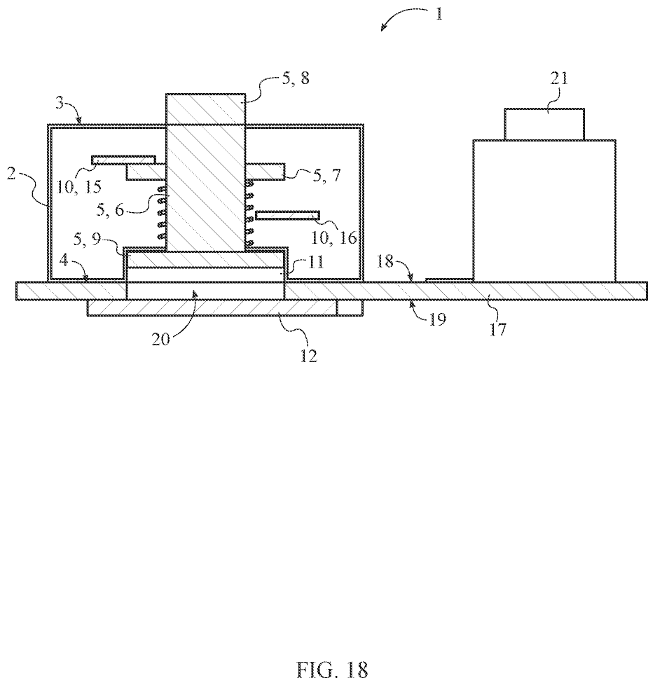

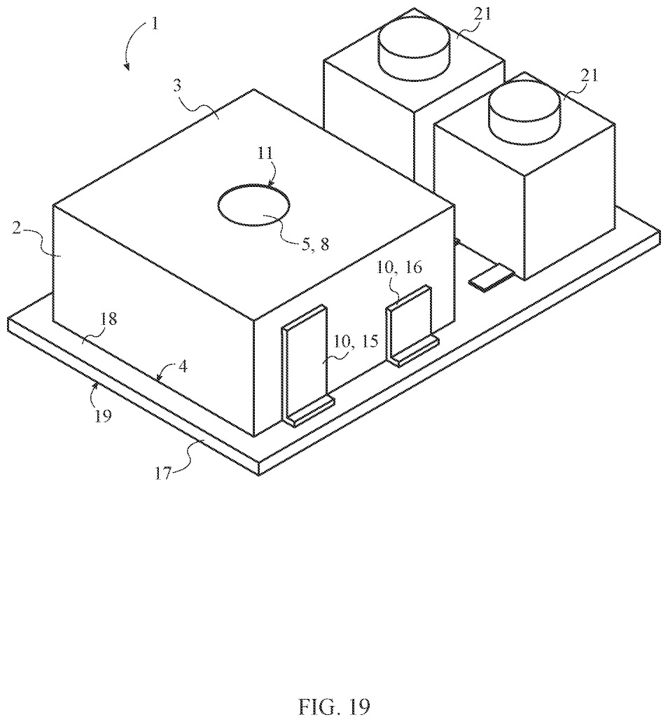

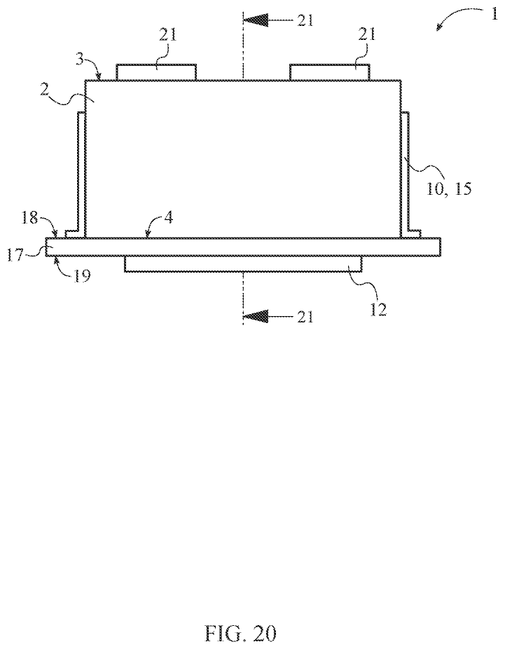

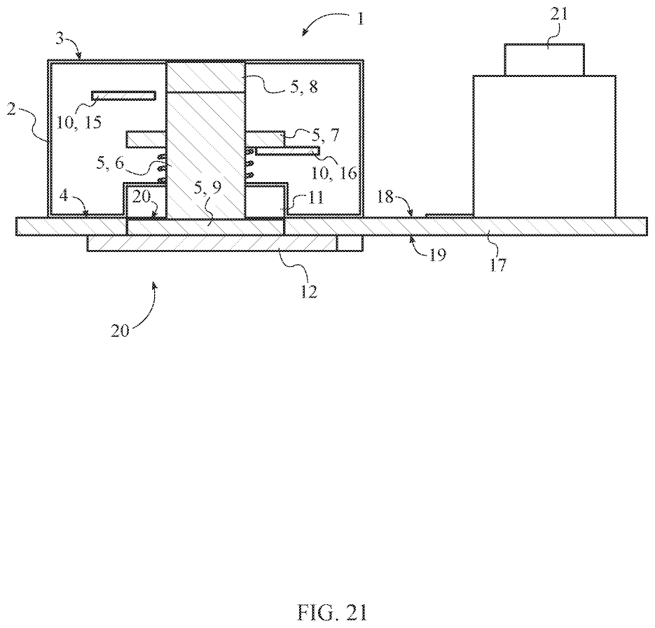

In a second embodiment, the switch housing 2 and the at least one pressure transducer 12 can be arranged in different locations throughout the at least one PCB 17. As can be seen in FIG. 13 through 21, the at least one PCB 17 may comprise a first board face 18, a second board face 19, and a plunger opening 20. The first board face 18 and the second board face 19 correspond to the two largest flat surfaces of the at least one PCB 17. The plunger opening 20 allows the switch plunger 5 to contact the at least one pressure transducer 12 through the at least one PCB 17. Accordingly, the first board face 18 is positioned opposite to the second board face 19 across the at least one PCB 17 due to the overall flat design of the at least one PCB 17. The plunger opening 20 traverses through the at least one PCB 17 to allow the switch plunger 5, specifically the second plunger end 9, to pass through the at least one PCB 17. Further, the plunger channel 11 is positioned coincident with the plunger opening 20 to allow the second plunger end 9 to pass through the plunger opening 20. In the second embodiment, the switch housing 2 is preferably mounted onto the first board face 18, while the at least one pressure transducer 12 is mounted onto the second board face 19. Thus, when the user presses the first plunger end 8 into the plunger channel 11, the spring-loaded body 6 moves the second plunger end 9 out of the switch housing 2, through the plunger opening 20, until the second plunger end 9 contacts the at least one pressure transducer 12. In other embodiments, different arrangements of the at least one push button switch 1 and the at least one pressure transducer 12 can be implemented on the at least one PCB 17, such as locating the at least one pressure transducer 12 on the first board face 18 and directly under the second plunger end 9.

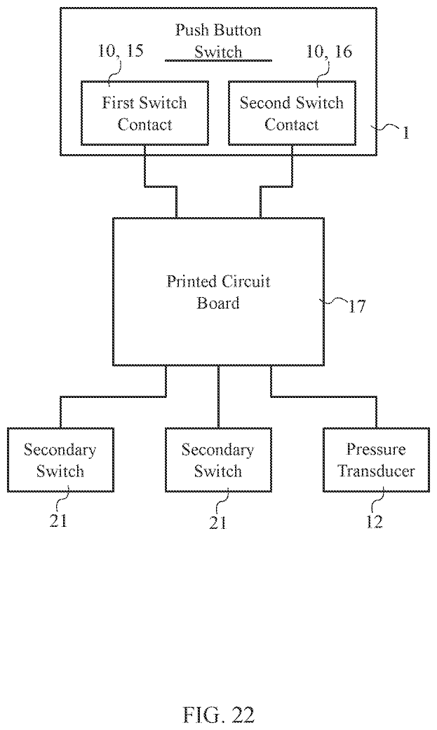

Further, as can be seen in FIG. 22, the at least one switch contact 10 and the at least one pressure transducer 12 are electronically connected to the at least one PCB 17 to relay the electrical and electronical signals to the at least one PCB 17. Furthermore, additional electrical and/or electronic components can be implemented on the at least one PCB 17 to further enhance the functionality of the present invention. For example, as can be seen in FIG. 11 through 22, the present invention may further include a plurality of secondary switches 21 that can be used to activate different functions on the host application. For example, the plurality of secondary switches 21 can include, but is not limited to, a forward switch and a reverse switch that enable the control of the directional operation of one or more electrical components of the host application. The plurality of secondary switches 21 can also be mounted onto the at least one PCB 17 and positioned offset to the at least one push button switch 1 to facilitate access to any switch. Further, the plurality of secondary switches 21 can be electronically connected to the at least one PCB 17 to relay the appropriate command signals to the host application. In other embodiments, different components can be implemented to enhance the functionality of the present invention.

Although the invention has been explained in relation to its preferred embodiment, it is to be understood that many other possible modifications and variations can be made without departing from the spirit and scope of the invention.

What is claimed is:

1. A high-reliability multi-function switch comprising:
at least one push button switch;
at least one pressure transducer;
the at least one push button switch comprising a switch housing, a switch plunger, at least one switch contact, and a plunger channel;
the plunger channel traversing through the switch housing;
the at least one switch contact being mounted within the switch housing;
the at least one switch contact being positioned adjacent to the switch plunger;
the switch plunger being slidably mounted within the plunger channel such that when the plunger is in a resting configuration, a terminal end of the plunger is positioned external to the switch housing, and when in a pressed configuration, an opposite terminal end of the plunger is positioned external to the switch housing; and
the at least one pressure transducer being mechanically co-located with the switch plunger along the plunger channel.

2. The high-reliability multi-function switch as claimed in claim 1 comprising:
the switch plunger comprising a spring-loaded body, at least one body contact, a first plunger end, and a second plunger end;
the switch housing comprising a first housing face and a second housing face;
the first plunger end being positioned opposite to the second plunger end along the spring-loaded body;
the first housing face being positioned opposite to the second housing face across the switch housing;
the plunger channel traversing from the first housing face to the second housing face;
the spring-loaded body being slidably mounted within the plunger channel;
the at least one body contact being laterally mounted onto the spring-loaded body;
the first plunger end being positioned adjacent to the first housing face;
the second plunger end being positioned adjacent to the second housing face;
the at least one pressure transducer being positioned adjacent to the second housing face; and
the at least one pressure transducer being axially aligned with the second plunger end.

3. The high-reliability multi-function switch as claimed in claim 2, wherein the switch plunger is positioned in the resting configuration, the first plunger end is positioned external to the plunger channel, the at least one body contact is positioned offset the at least one switch contact, and the second plunger end is positioned within the plunger channel.

4. The high-reliability multi-function switch as claimed in claim 2, wherein the switch plunger is positioned in the pressed configuration, the first plunger end is positioned within the plunger channel, the at least one body contact is in electrical contact with the at least one switch contact, the second plunger end is positioned external to the plunger channel, and the second plunger end is in physical contact with the at least one pressure transducer.

5. The high-reliability multi-function switch as claimed in claim 2 comprising:
a hermetic seal;
the hermetic seal comprising a button interface;
the button interface being externally and hermetically integrated into the hermetic seal;
the at least one push button switch and the at least one pressure transducer being mounted within the hermetic seal; and
the first plunger end being positioned adjacent to the button interface.

6. The high-reliability multi-function switch as claimed in claim 1 comprising:
the at least one switch contact being a first switch contact and a second switch contact;
the switch plunger comprising a spring-loaded body and at least one body contact;
the switch housing comprising a first housing face and a second housing face;
the first housing face being positioned opposite to the second housing face across the switch housing;
the plunger channel traversing from the first housing face to the second housing face;
the spring-loaded body being slidably mounted within the plunger channel;
the at least one body contact being laterally mounted onto the spring-loaded body;
the first switch contact being positioned adjacent to the first housing face; and
the second switch contact being positioned adjacent to the second housing face.

7. The high-reliability multi-function switch as claimed in claim 6, wherein the switch plunger is positioned in the resting configuration, the at least one body contact is positioned offset to the second switch contact, and the at least one body contact is in electrical contact with the first switch contact.

8. The high-reliability multi-function switch as claimed in claim 6, wherein the switch plunger is positioned in the pressed configuration, the at least one body contact is positioned offset to the first switch contact, and the at least one body contact is in electrical contact with the second switch contact.

9. The high-reliability multi-function switch as claimed in claim 1 comprising:
at least one printed circuit board (PCB);
the at least one pressure transducer being mounted onto a first board face of the at least one PCB;
the switch housing being mounted onto the first board face such that the movement of the switch plunger applies pressure to the surface of the at least one pressure transducer; and
the at least one switch contact and the at least one pressure transducer being electronically connected to the at least one PCB.

10. The high-reliability multi-function switch as claimed in claim 1 comprising:
at least one printed circuit board (PCB);
the at least one PCB comprising a first board face, a second board face, and a plunger opening;
the first board face being positioned opposite to the second board face across the at least one PCB;
the plunger opening traversing from the first board face, through the at least one PCB, to the second board face;
the plunger channel being positioned coincident with the plunger opening;
the switch housing being mounted onto the first board face;
the at least one pressure transducer being mounted onto the second board face; and
the at least one switch contact and the at least one pressure transducer being electronically connected to the at least one PCB.

11. A high-reliability multi-function switch comprising:
at least one push button switch;
at least one pressure transducer;
the at least one push button switch comprising a switch housing, a switch plunger, at least one switch contact, and a plunger channel;
the switch plunger comprising a spring-loaded body, at least one body contact, a first plunger end, and a second plunger end;
the switch housing comprising a first housing face and a second housing face;
the first plunger end being positioned opposite to the second plunger end along the spring-loaded body;
the first housing face being positioned opposite to the second housing face across the switch housing;
the plunger channel traversing from the first housing face to the second housing face;
the spring-loaded body being slidably mounted within the plunger channel;
the at least one body contact being laterally mounted onto the spring-loaded body;
the first plunger end being positioned adjacent to the first housing face;
the second plunger end being positioned adjacent to the second housing face;
the at least one switch contact being mounted within the switch housing;
the at least one switch contact being positioned adjacent to the switch plunger;
the switch plunger being slidably mounted within the plunger channel such that when the plunger is in a resting configuration, a terminal end of the plunger is positioned external to the switch housing, and when in a pressed configuration, an opposite terminal end of the plunger is positioned external to the switch housing;
the at least one pressure transducer being positioned adjacent to the second housing face;
the at least one pressure transducer being axially aligned with the second plunger end; and
the at least one pressure transducer being mechanically co-located with the switch plunger along the plunger channel.

12. The high-reliability multi-function switch as claimed in claim 11, wherein the switch plunger is positioned in the resting configuration, the first plunger end is positioned external to the plunger channel, the at least one body contact is positioned offset the at least one switch contact, and the second plunger end is positioned within the plunger channel.

13. The high-reliability multi-function switch as claimed in claim 11, wherein the switch plunger is positioned in the pressed configuration, the first plunger end is positioned within the plunger channel, the at least one body contact is in electrical contact with the at least one switch contact, the second plunger end is positioned external to the plunger channel, and the second plunger end is in physical contact with the at least one pressure transducer.

14. The high-reliability multi-function switch as claimed in claim 11 comprising:
a hermetic seal;
the hermetic seal comprising a button interface;
the button interface being externally and hermetically integrated into the hermetic seal;
the at least one push button switch and the at least one pressure transducer being mounted within the hermetic seal; and
the first plunger end being positioned adjacent to the button interface.

15. The high-reliability multi-function switch as claimed in claim 11 comprising:
the at least one switch contact being a first switch contact and a second switch contact;
the switch plunger comprising a spring-loaded body and at least one body contact;
the switch housing comprising a first housing face and a second housing face;
the first housing face being positioned opposite to the second housing face across the switch housing;
the plunger channel traversing from the first housing face to the second housing face;
the spring-loaded body being slidably mounted within the plunger channel;
the at least one body contact being laterally mounted onto the spring-loaded body;
the first switch contact being positioned adjacent to the first housing face; and
the second switch contact being positioned adjacent to the second housing face.

16. The high-reliability multi-function switch as claimed in claim 15, wherein the switch plunger is positioned in the resting configuration, the at least one body contact is positioned offset to the second switch contact, and the at least one body contact is in electrical contact with the first switch contact.

17. The high-reliability multi-function switch as claimed in claim 15, wherein the switch plunger is positioned in the pressed configuration, the at least one body contact is positioned offset to the first switch contact, and the at least one body contact is in electrical contact with the second switch contact.

18. The high-reliability multi-function switch as claimed in claim 11 comprising:
at least one printed circuit board (PCB);
the at least one pressure transducer being mounted onto a first board face of the at least one PCB;
the switch housing being mounted onto the first board face such that the movement of the switch plunger applies pressure to the surface of the at least one pressure transducer; and
the at least one switch contact and the at least one pressure transducer being electronically connected to the at least one PCB.

19. The high-reliability multi-function switch as claimed in claim 11 comprising:
at least one printed circuit board (PCB);
the at least one PCB comprising a first board face, a second board face, and a plunger opening;
the first board face being positioned opposite to the second board face across the at least one PCB;
the plunger opening traversing from the first board face, through the at least one PCB, to the second board face;
the plunger channel being positioned coincident with the plunger opening;
the switch housing being mounted onto the first board face;
the at least one pressure transducer being mounted onto the second board face; and
the at least one switch contact and the at least one pressure transducer being electronically connected to the at least one PCB.
